(19) United States
(12) Patent Application Publication
(10) Pub. No.: US 2022/0067986 A1
(43) Pub. Date: Mar. 3, 2022

(54) DATA RECONSTRUCTION DEVICE, DATA RECONSTRUCTION METHOD, AND NON-VOLATILE COMPUTER-READABLE STORAGE MEDIUM STORING THEREIN DATA RECONSTRUCTION PROGRAM

(71) Applicant: CANON MEDICAL SYSTEMS CORPORATION, Otawara-shi (JP)

(72) Inventor: Hidenori TAKESHIMA, Kawasaki (JP)

(73) Assignee: CANON MEDICAL SYSTEMS CORPORATION, Otawara-shi (JP)

(21) Appl. No.: 17/409,885

(22) Filed: Aug. 24, 2021

(30) Foreign Application Priority Data
Aug. 28, 2020 (JP) 2020-144102

(51) Int. Cl. G06T 11/00

(52) U.S. Cl. CPC G06T 11/005; G06T 2210/32; G06T 2210/41

(57) ABSTRACT

A data reconstruction device according to an embodiment of the present disclosure includes processing circuitry. The processing circuitry is configured to generate a medical image of an image type different from that of reference data on the basis of the reference data. The processing circuitry is configured to obtain acquisition data acquired by using an acquisition method different from that used for data to be generated related to generating the reference data. The processing circuitry is configured to generate a reconstruction image of the image type by correcting inconsistency of the medical image with the acquisition data on the basis of the medical image, the acquisition data, and the reference data.

### CROSS-REFERENCE TO RELATED APPLICATIONS

This application is based upon and claims the benefit of priority from Japanese Patent Application No. 2020-144102, filed on Aug. 28, 2020; the entire contents of which are incorporated herein by reference.

### FIELD

Embodiments described herein relate generally to a data reconstruction device, a data reconstruction method, and a non-volatile computer-readable storage medium storing therein a data reconstruction program.

### BACKGROUND

For Magnetic Resonance Imaging (hereinafter, “MRI”) apparatuses, techniques (e.g., synthetic MR, fingerprinting) are conventionally known by which, after an imaging process, a calculated image of an arbitrary image type is generated through calculation, by using an MR image obtained by the imaging process that uses a sequence including various elements, together with an arbitrary parameter value. These techniques are realized as, for example, image synthesis and image reconstruction using a model. The image synthesis and the image reconstruction using a model are strongly dependent on dictionaries and prior knowledge of reconstruction methods. For this reason, calculated images generated through the image synthesis and the image reconstruction using a model correspond to images predicted by using these techniques. Further, an image reconstruction scheme is known by which a T1-weighted (T1W) image is generated by inputting a high-reduction T1W image and a low-reduction T2-weighted (T2W) image.

Reliability may be degraded in the calculated images generated through the reconstruction using the abovementioned technique that is strongly dependent on prior knowledge. For example, images related to synthetic Fluid attenuated IR (FLAIR) may have lower reliability (e.g., a normal structure may exhibit a lower contrast noise ratio) than images obtained by applying a conventional FLAIR method. In other words, there is a problem where it would not be easy to ensure reliability of images generated through these techniques.

### BRIEF DESCRIPTION OF THE DRAWINGS

FIG. 1 is a block diagram illustrating an example of a data reconstruction device 1 according to a first embodiment;

FIG. 2 is a diagram illustrating an example of an outline of a reconstruction process according to the first embodiment;

FIG. 3 is a flowchart illustrating an example of a procedure in the reconstruction process according to the first embodiment;

FIG. 4 is a diagram illustrating an example of an outline of a reconstruction training process according to the first embodiment;

FIG. 5 is a flowchart illustrating an example of a procedure in the reconstruction training process according to the first embodiment;

FIG. 6 is a diagram illustrating an example of an outline of a reconstruction process according to a modification example of the first embodiment;

FIG. 7 is a flowchart illustrating an example of a procedure in the reconstruction process according to the modification example of the first embodiment; and

FIG. 8 is a diagram illustrating an example of an MRI apparatus according to a second embodiment.

### DETAILED DESCRIPTION

Exemplary embodiments of a data reconstruction device, a data reconstruction method, and a non-volatile computer-readable storage medium storing therein a data reconstruction program will be explained in detail below, with reference to the accompanying drawings.

A data reconstruction device described in the following embodiments includes processing circuitry. The processing circuitry is configured to generate a medical image of an image type different from that of reference data on the basis of the reference data. The processing circuitry is configured to obtain acquisition data acquired by using an acquisition method different from that used for data to be generated related to generating the reference data. The processing circuitry is configured to generate a reconstruction image of the image type by correcting inconsistency of the medical image with the acquisition data on the basis of the medical image, the acquisition data, and the reference data.

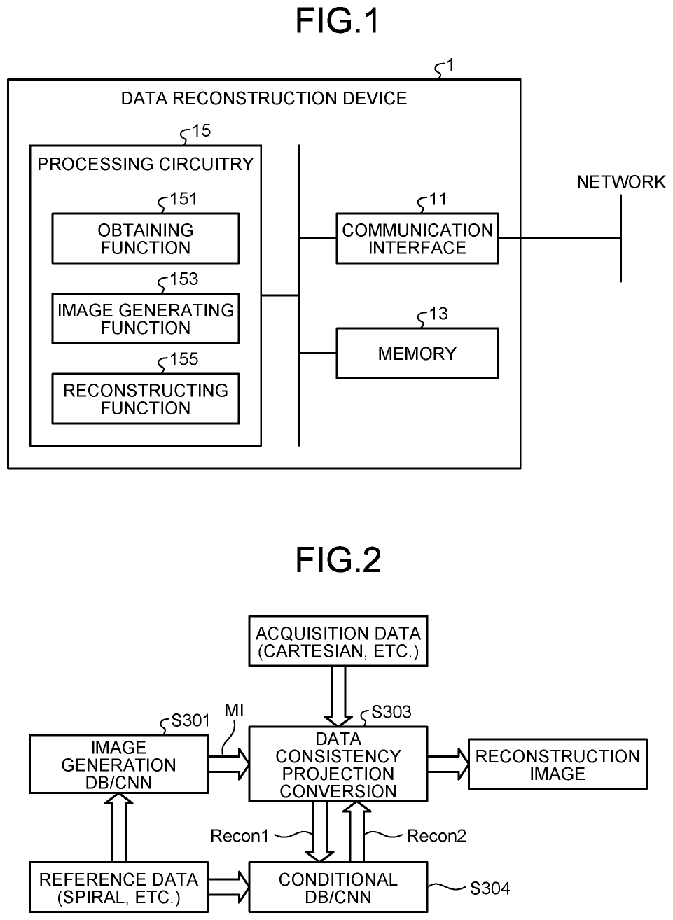

FIG. 1 is a block diagram illustrating an example of a data reconstruction device 1. It is possible to apply technical concepts of the present embodiments to any of various types of modalities capable of generating medical images. In this situation, examples of the modalities include a Magnetic Resonance Imaging (hereinafter, “MRI”) apparatus and an X-ray Computed Tomography (hereinafter, “CT”) apparatus. Later in a second embodiment, an example using an MRI apparatus as one of the modalities will be explained. In that situation, the MRI apparatus includes various types of functions of processing circuitry 15.

### First Embodiment

The data reconstruction device 1 includes a communication interface 11, a memory 13, and the processing circuitry 15. As illustrated in FIG. 1, in the data reconstruction device 1, the communication interface 11, the memory 13, and the processing circuitry 15 are electrically connected to one another via a bus. As illustrated in FIG. 1, the data reconstruction device 1 is connected to a network, via the communication interface 11. To the network, various types of modalities, a Hospital information System (hereinafter, “HIS”), a medical image management system (hereinafter, “Picture Archiving and Communication System [PACS]”), and the like are connected. Further, the data reconstruction device 1 may include an input interface used for inputting various types of information of a user and a display device (an output interface) configured to display a reconstruction image reconstructed by a reconstructing function 155.

The communication interface 11 is configured to perform data communication, for example, with any of the various types of modalities that images an examined subject during a medical examination performed on an examined subject and with the HIS, the PACS, and/or the like. The standard used for the communication between the communication interface 11 and the various types of modalities and the hospital information system may be any standard. It is possible to use one or both of Health Level 7 (HL7) and a Digital Imaging and Communications in Medicine (DICOM).

The memory 13 is realized by using storage circuitry configured to store therein various types of information. For example, the memory 13 is a storage device such as a Hard Disk Drive (HDD), a Solid State Drive (SSD), or an integrated circuit storage device. The memory 13 corresponds to a storage unit. Instead of being an HDD, an SSD, or the like, the memory 13 may be a semiconductor memory element such as a Random Access Memory (RAM) or a flash memory; an optical disc such as a Compact Disc (CD) or a Digital Versatile Disc (DVD); a portable storage medium; or a drive device that reads and writes various types of information to and from a semiconductor memory element such as a RAM.

The memory 13 is configured to store therein various types of data received by an obtaining function 151 via the communication interface 11. The received various types of data may be, for example, reference data, acquisition data, and the like. The reference data corresponds to a medical image reconstructed in advance by using data to be generated related to generating the reference data. In other words, the reference data is data generated by using the data to be generated that has already been acquired in advance. In this situation, the image corresponding to the reference data and the reconstruction image (explained later) may have mutually-different contrast levels. The reconstruction image is a medical image reconstructed by the reconstructing function 155 (explained later). In the following sections, to explain a specific example, the medical image is assumed to be a Magnetic Resonance (MR) image. In that situation, the data to be generated corresponds, for example, to k-space data (raw data) acquired by imaging an examined subject (hereinafter, “patient”) while using the MRI apparatus.

In this situation, the reference data may be data (e.g., a T1 map, a T2 map, or a AF map) obtained by mapping a parameter dependent on the patient (e.g., a T1 value being a time constant for a longitudinal magnetization recovery, a T2 value being a time constant for a transverse magnetization attenuation, or AF expressing a small change in a resonance frequency). The data obtained by mapping the parameter dependent on the patient is, for example, generated by magnetic resonance fingerprinting (hereinafter, simply “fingerprinting”). Further, the reference data may be a medical image generated through a synthetic MR process. The imaging related to the data to be generated may be performed by using a pulse sequence for obtaining k-space data capable of generating a plurality of mutually-different contrast levels. The pulse sequence may be, for example, a sequence related to fingerprinting or synthetic MR. Further, the reference data may be an image generated on the basis of a scout image or data acquired prior to the imaging of the acquisition data. Further, the data to be generated may be acquired before acquiring the acquisition data.

The medical image does not necessarily have to be an MR image and may be a CT image or the like. In that situation, the data to be generated corresponds to projection data acquired by scanning the patient while using an X-ray CT apparatus, for example.

The acquisition data is data which is acquired by imaging the patient and which is, for example, different from the data to be generated and from the reference data. When the acquisition data is obtained by an MRI apparatus, the acquisition data is data acquired through an imaging process using a pulse sequence different from that of the data to be generated and corresponds to k-space data. For example, when the reference data is full-sampling k-space data, the acquisition data is k-space data acquired with a high under-sampling ratio where a reduction factor corresponding to a step size of under-sampling is, for example, in the range of 4 to 8. The acquisition data does not necessarily have to be k-space data and may be projection data or the like.

The acquisition data may be data acquired by using a sequence that does not coincide with a sequence used for obtaining k-space data capable of generating a plurality of mutually-different contrast levels or a sequence used for acquiring data capable of generating a reconstruction image desired by a user through an inverse Fourier transform. The sequence may be, for example, a sequence related to Synthetic MR or fingerprinting. In the following sections, to explain a specific example, the data acquired by the sequence will be assumed to be data acquired by fingerprinting (hereinafter, “fingerprinting data”). The fingerprinting is a method by which a quantitative value indicating the value of a parameter of an MR characteristic such as a T1 value or a T2 value is estimated by dictionary-based matching between a signal value waveform of a continual MR signal and a signal value waveform obtained by a simulation (predictive calculation).

Further, the imaging related to the acquiring of the acquisition data may be performed by using a pulse sequence for obtaining k-space data used for reconstructing medical images corresponding to a plurality of mutually-different contrast levels. Further, the acquisition data may be data acquired in a medical examination performed after the medical examination performed to acquire the data to be generated. In other words, the reference data may be data generated from a medical examination (an imaging process) performed earlier than the medical examination related to the acquiring of the acquisition data.

Further, the memory 13 is configured to store therein various types of data generated by the processing circuitry 15. The generated various types of data include, for example, various types of intermediate reconstruction images generated during a generation process of the reconstruction image performed by the reconstructing function 155 and a reconstruction image finally generated by the reconstructing function 155. The various types of data will be explained in detail later. Further, the memory 13 is configured to store therein a trained model (hereinafter, “generation model”) used in execution of an image generating function 153, a trained model (hereinafter, “reconstruction model”) used in execution of the reconstructing function 155, and the like. The reconstruction process may be referred to as a “style transfer”. Further, the memory 13 is configured to store therein, for example, a plurality of reconstruction models corresponding to the number of times N (where N is a predetermined natural number of 1 or larger) indicating how many times (hereinafter, “repetition number”) the reconstructing function 155 is capable of repeatedly generating intermediate reconstruction images.

Instead of the reconstruction models, the memory 13 may store therein, as a generation model, a database (hereinafter, “generation database [DB]”) used in the execution of the image generating function 153. Further, as for the memory 13, when the acquisition data is fingerprinting data, the memory 13 is configured to store therein a conditional database (hereinafter, “reconstruction database [DB]”) related to generation of a reconstruction image using dictionary matching. The generation model, the generation DB, the reconstruction model, and the reconstruction DB correspond to a technique that uses prior knowledge for relationships of inputs/outputs and are stored in the memory 13 in correspondence with image types being input and image types being output. The generation model, the generation DB, the reconstruction model, and the reconstruction DB may each be an element (e.g., a complex neural network) corresponding to application of a complex number image (e.g., an absolute value image or a phase image). The generation model, the generation DB, the reconstruction model, and the reconstruction DB will be explained later.

The processing circuitry 15 is configured to control the entirety of the data reconstruction device 1. More specifically, the processing circuitry 15 includes, for example, the obtaining function 151, the image generating function 153, the reconstructing function 155, and the like. The processing circuitry 15 that realizes the obtaining function 151, the image generating function 153, and the reconstructing function 155 corresponds to an obtaining unit, an image generating unit, and a reconstructing unit, respectively. Functions such as the obtaining function 151, the image generating function 153, and the reconstructing function 155 are stored in the memory 13 in the form of computer-executable programs. The processing circuitry 15 is one or more processors. For example, the processing circuitry 15 is configured to realize the functions corresponding to the programs by reading and executing the programs from the memory 13. In other words, the processing circuitry 15 that has read the programs has the functions such as the obtaining function 151, the image generating function 153, and the reconstructing function 155.

In the description above, the example was explained in which the one or more “processors” read and execute the programs corresponding to the functions from the memory 13; however, possible embodiments are not limited to this example. The term “processor” denotes, for example, a Central Processing Unit (CPU), a Graphics Processing Unit (GPU), or circuitry such as an Application Specific Integrated Circuit (ASIC) or a programmable logic device (e.g., a Simple Programmable Logic Device [SPLD], a Complex Programmable Logic Device [CPLD], or a Field Programmable Gate Array [FPGA]).

When the one or more processors are each a CPU, for example, the processor realizes the functions by reading and executing the programs saved in the memory 13. In contrast, when the one or more processors are each an ASIC, the functions are directly incorporated in the circuitry of the processor as logic circuitry, instead of the programs being saved in the memory 13. Further, the processors according to the present embodiments do not each necessarily have to be structured as a single piece of circuitry. It is also acceptable to structure one processor by combining together a plurality of pieces of independent circuitry so as to realize the functions thereof. Further, although the example was explained in which the single piece of storage circuitry stores therein the programs corresponding to the processing functions, it is also acceptable to arrange a plurality of pieces of storage circuitry in a distributed manner, so that the processing circuitry reads a corresponding program from each of the individual pieces of storage circuitry.

By employing the obtaining function 151, the processing circuitry 15 is configured to obtain the reference data via the network. For example, via the communication interface 11, the obtaining function 151 is configured to obtain the reference data from the HIS or the PACS. The obtaining function 151 is configured to store the reference data into the memory 13. The obtaining function 151 is configured to obtain the acquisition data acquired with respect to the patient, from a modality via the network. For example, via the communication interface 11, the obtaining function 151 is configured to obtain the acquisition data from the MRI apparatus. Alternatively, the obtaining function 151 may obtain the acquisition data from the HIS or the PACS. The obtaining function 151 is configured to store the acquisition data into the memory 13.

By employing the image generating function 153, the processing circuitry 15 is configured to generate, on the basis of the reference data, a medical image of an image type different from that of the reference data. For example, the image generating function 153 reads the generation model from the memory 13. By inputting the reference data to the read generation model, the image generating function 153 generates the medical image. The generated medical image corresponds to a prediction image of the pertinent image type based on prior knowledge. For example, when the reference data is a T1-weighted image (hereinafter, “T1W”), whereas the medical image is a T2-weighted image (hereinafter, “T2W”), the generation model corresponds to a trained model that has trained in advance to receive an input of a T1W and to output a T2W. In other words, the generation model is a trained model that has been trained in advance to generate a medical image of an image type different from that of the input medical image. Alternatively, instead of the generation model, the image generating function 153 may use the generation DB to generate a T2W in response to the input of the T1W.

By employing the reconstructing function 155, the processing circuitry 15 is configured to generate the reconstruction image of the same image type as that of the medical image, by correcting inconsistency of the medical image with the acquisition data, on the basis of the medical image, the acquisition data, and the reference data. For example, the reconstructing function 155 generates a first intermediate reconstruction image by using the medical image, so as to reduce inconsistency with the acquisition data. The reconstructing function 155 inputs the reference data serving as a condition and inputs the first intermediate reconstruction image to a conditional trained model configured to receive an input of the first intermediate reconstruction image and the reference data and to output a second intermediate reconstruction image. The reconstructing function 155 generates, as the reconstruction image, the second intermediate reconstruction image which was output from the conditional trained model in response to the input and in which the inconsistency between the first intermediate reconstruction image and the acquisition data has been corrected.

The conditional trained model corresponds to the abovementioned reconstruction model and is realized by using, for example, a conditional Generative Adversarial Network (cGAN) configured to input a condition (the reference data) to a generator. However, the reconstruction model does not necessarily have to be a cGAN and may be realized by using a Deep Neural Network (DNN) such as a conditional Convolutional Neural Network (CNN). Further, when the acquisition data is fingerprinting data, the reconstruction DB is used in place of the reconstruction model.

The processes of generating the first intermediate reconstruction image, the second intermediate reconstruction image, and the reconstruction image will be explained when explaining a procedure in the process (hereinafter, “reconstruction process”) of generating the reconstruction image having enhanced reliability. Details of the reconstruction model and the reconstruction DB will be explained when explaining a procedure in a process (hereinafter, “reconstruction training process”) related to generating the reconstruction model and the reconstruction through training processes.

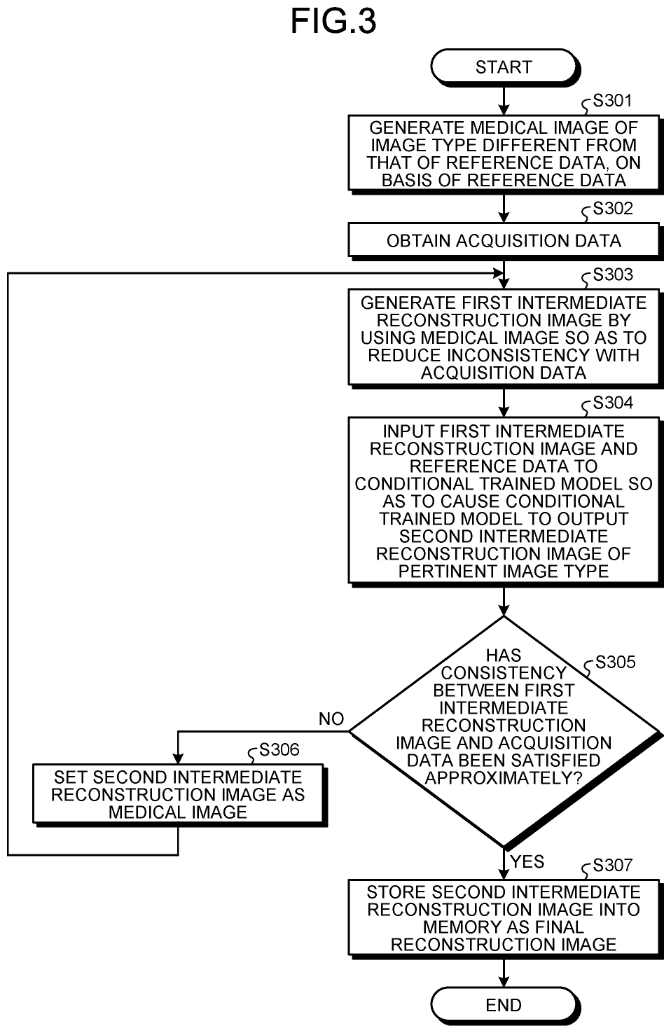

A reconstruction process performed by the data reconstruction device 1 according to the present embodiment structured as described above will be explained, with reference to FIGS. 2 and 3. FIG. 2 is a diagram illustrating an example of an outline of the reconstruction process. FIG. 3 is a flowchart illustrating an example of a procedure in the reconstruction process according to the first embodiment.

The reconstruction process

### Step S301:

As illustrated in FIGS. 2 and 3, with respect to the reference data obtained by the obtaining function 151, the image generating function 153 generates a medical image MI of an image type different from that of the reference data. As illustrated in FIG. 2, an example will be explained in which the reference data is assumed to be, for instance, a T1W generated by using data to be generated obtained through a spiral scan. Further, the image type of the medical image MI generated at the present step is assumed to be set as a T2W, for example, according to an instruction from the user via an input interface. More specifically, the image generating function 153 generates the T2W by inputting the reference data to the generation model configured to receive a T1W and to output a T2W.

### Step S302:

By employing the obtaining function 151, the processing circuitry 15 obtains acquisition data. The acquisition data may be, for example, k-space data acquired through parallel imaging having a reduction factor of 4 to 8 in a Cartesian scan. In other words, a data amount of the acquisition data is smaller than that of the data to be generated. That is to say, the acquisition data is acquired over an imaging period shorter than the imaging period for obtaining the data to be generated. To explain a specific example, it will be assumed that the reduction factor of the imaging related to the data to be generated is 1, whereas the reduction factor of the acquisition data is 8.

### Step S303:

By employing the reconstructing function 155, the processing circuitry 15 generates a first intermediate reconstruction image Recon1 by using the medical image, so as to reduce inconsistency with the acquisition data. For example, the reconstructing function 155 generates the first intermediate reconstruction image Recon1 by using the medical image MI, while implementing a conjugate gradient method similar to an Alternating Direction Method of Multipliers (ADMM) so as to make the first intermediate reconstruction image Recon1 and the acquisition data consistent with each other. The process at the present step corresponds to a process of generating the first intermediate reconstruction image Recon1 by optimizing consistency between the acquisition data and intermediate conversion data generated by converting the generated first intermediate reconstruction image Recon1 into data in the same format as that of the acquisition data. This conversion corresponds to a simulation from an image to k-space data.

The optimization method used for the process at the present step is not limited to the ADMM and the conjugate gradient method. When the reduction factor of the acquisition data is 8, the intermediate conversion data corresponds to k-space data of which the reduction factor is 8. The process at the present step corresponds to a process of converting the first intermediate reconstruction image Recon1 into the intermediate conversion data (through projection process, for example) and subsequently compensating the data consistency between the medical image MI and the acquisition data. The process thus corresponds to a data consistency projection conversion illustrated in FIG.

### Step S304:

By employing the reconstructing function 155, the processing circuitry 15 inputs the first intermediate reconstruction image Recon1 and the reference data to the conditional trained model, i.e., the reconstruction model, so that the reconstruction model outputs a second intermediate reconstruction image Recon2 of the pertinent image type. When the data to be generated or the acquisition data is fingerprinting data, the reconstructing function 155 uses the reconstruction DB in place of the reconstruction model. At the present step, the first intermediate reconstruction image Recon1 brought into consistency with the acquisition data and the reference data have been input to the reconstruction model, so that the second intermediate reconstruction image Recon2 using the reference data as a condition is generated. The process at the present step corresponds to the conditional DB/CNN illustrated in FIG. 2.

### Step S305:

When the consistency between the first intermediate reconstruction image Recon1 and the acquisition data has been satisfied approximately (step S305: Yes), the process at step S307 will be performed. For example, when the difference between the intermediate conversion data derived from the first intermediate reconstruction image Recon1 and the acquisition data at step S303 is equal to or smaller than a prescribed value, the process at step S307 will be performed. On the contrary, when the consistency between the first intermediate reconstruction image Recon1 and the acquisition data has not been satisfied approximately (Step S305: No), the process at step S306 will be performed. For example, when the difference between the intermediate conversion data derived from the first intermediate reconstruction image Recon1 and the acquisition data at step S303 exceeds the prescribed value, the process at step S306 will be performed. The prescribed value is a value indicating the degree of consistency between the intermediate conversion data derived from the first intermediate reconstruction image Recon1 and the acquisition data and, for example, may arbitrarily be set in accordance with the image type of the reconstruction image. Step S306:

The reconstructing function 155 sets the second intermediate reconstruction image Recon2 as a medical image to be used in the process at step S303. In other words, the reconstructing function 155 makes an update by using the second intermediate reconstruction image Recon2 as a new medical image. Subsequently, the processes at step S303 and thereafter will be repeated by using the updated medical image. The repetition at steps S303 through S306 is depicted in FIG. 2 by the two arrows placed between the data consistency projection conversion and the conditional DB/CNN. Step S307:

By employing the reconstructing function 155, the processing circuitry 15 sets the second intermediate reconstruction image Recon2 generated at step S304 as a final reconstruction image. The memory 13 stores the image therein as the final reconstruction image. In this situation, the processing circuitry 15 may transmit the final reconstruction image to an external modality, the PACS, or the HIS, via the communication interface 11. The final reconstruction image is illustrated in FIG. 2 as the reconstruction image. The reconstruction process has thus ended.

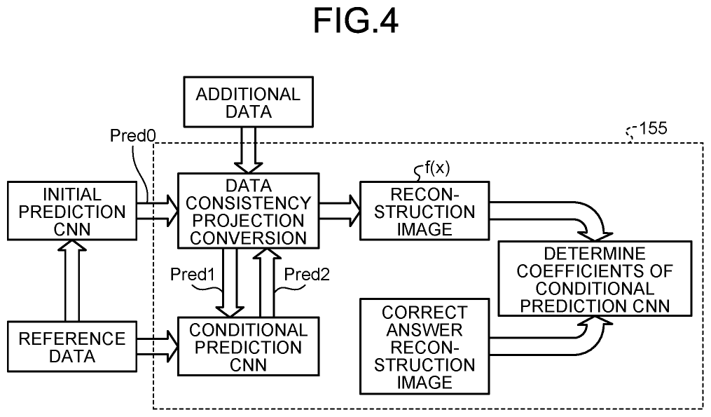

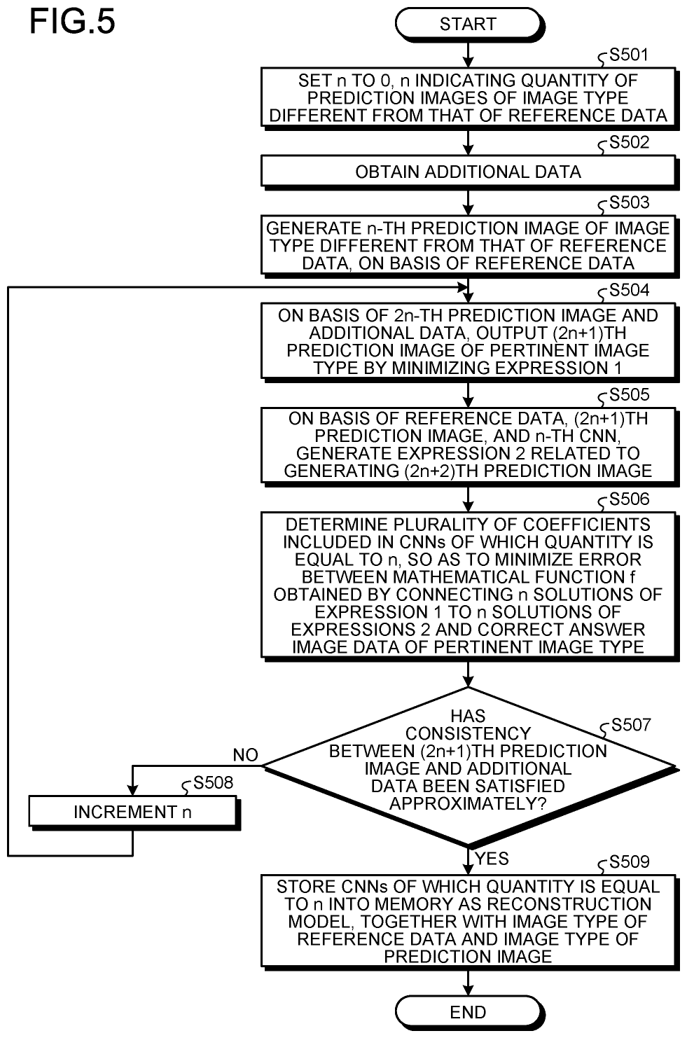

Next, the reconstruction training process to generate, through a training process, the reconstruction model used in the reconstruction process described above will be explained, with reference to FIGS. 4 and 5. FIG. 4 is a diagram illustrating an example of an outline of the reconstruction training process. FIG. 5 is a flowchart illustrating an example of a procedure in the reconstruction training process. In the following sections, the output from an initial prediction CNN will be referred to as a 0th prediction image Pred0. In addition, to avoid confusion between the first intermediate reconstruction image Recon1 and the second intermediate reconstruction image Recon2 in the reconstruction process, in FIG. 4, the data output from the data consistency projection conversion to the conditional prediction CNN will be referred to as a (2n+1)th prediction image Pred1, whereas the data output from the conditional prediction CNN to the data consistency projection conversion will be referred to as a (2n+2)th prediction image Pred2. In this situation, n is an integer of 0 or larger expressing the quantity (hereinafter, “prediction index”) of the prediction images that are of an image type different from that of the reference data. Further, to avoid confusion with the acquisition data in the reconstruction process, the data corresponding to the acquisition data will be referred to as additional data. An example in which the reconstruction DB is generated through a training process will be explained later. One or more processes performed in the reconstruction training process described below may be performed by a training function to be included in the processing circuitry 15. In that situation, the processing circuitry 15 realizing the training function corresponds to a training unit.

The initial prediction CNN illustrated in FIG. 4 corresponds to the image generation DB/CNN illustrated in FIG. 2. The training of the initial prediction CNN is realized by determining a plurality of coefficients in the initial prediction CNN, by implementing a backpropagation method (an error backpropagation method) on an error between an output image from the initial prediction CNN and a medical image of the image type of a correct answer, while keeping the input and the output with mutually-different image types.

The reconstruction training process

### Step S501:

Prior to performing the reconstruction training process, the processing circuitry 15 sets the prediction index n to 0. The situation where n=0 is satisfied corresponds to the situation where the 0th prediction image Pred0 has been output from the initial prediction CNN. When being 1 or larger, the prediction index n is relevant to the quantity of the prediction images output by the reconstruction model or the reconstruction DB subject to the training. The natural numbers 1 to n correspond to the repetition number of the recontraction training process.

### Step S502:

By employing the obtaining function 151, the processing circuitry 15 obtains the additional data from the memory 13 or the like. Because the process of obtaining the additional data is the same as the process of obtaining the acquisition data at step S302, the explanation thereof will be omitted. Further, because the format of the additional data is the same data format as that of the acquisition data, the explanation thereof will be omitted. Also, the obtaining function 151 obtains the reference data from the memory 13 or the like.

### Step S503:

By employing the image generating function 153, on the basis of the reference data, the processing circuitry 15 generates an n-th prediction image (the 0th prediction image) Pred0 of an image type different from that of the reference data. An example will be explained by assuming, for example, that the reference data is a T1W generated by using data to be generated obtained through a spiral scan. Further, the image type of the 0th prediction image Pred0 generated at the present step is assumed to be set as a T2W, for example. More specifically, the image generating function 153 generates the T2W as the 0th prediction image Pred0, by inputting the reference data to the initial prediction CNN configured to receive an input of a T1W and to output a T2W.

### Step S504:

By employing the reconstructing function 155, the processing circuitry 15 predicts and outputs a (2n+1)th prediction image Pred1 of the pertinent image type, by minimizing Expression 1 on the basis of the 2n-th prediction image and the acquisition data. For example, Expression 1 may be expressed as presented below.

||Fx₂ₙ₊₁−k||₂²+λ₁||x₂ₙ₊₁−z₂ₙ||₂² Expression 1:

In Expression 1, F denotes a Fourier transform, whereas x₂₊₁ denotes the (2n+1)th prediction image Pred1, k denotes the additional data, x₂ₙ denotes a (2n)th prediction image, and λ₁ denotes a prescribed coefficient. Further, when the additional data k is data acquired through parallel imaging, Fx₂ₙ₊₁ is changed to the expression FSx₂ₙ₊₁ by using sensitivity information S. The elements in Expression 1 are expressed by using complex numbers. The minimization of Expression 1 corresponds to an equation in which differential with respect to x in Expression 1 is equal to 0 and may be derived by implementing a conjugate gradient method, for example. In this situation, when a mathematical function obtained by minimizing Expression 1 is expressed as g(n), it is possible to express the (2n+1)th prediction image x₂ₙ₊₁ with an expression (x₂ₙ₊₁=g(n)×x₂ₙ) that uses g(n)×x₂ₙ. Further, as a result of minimizing Expression 1, consistency between the Fourier transform of the (2n+1)th prediction image (i.e., Fx₂ₙ₊₁) and the additional data k is enhanced. In other words, the data consistency between the (2n+1)th prediction image x₂ₙ₊₁ and the additional data k is enhanced (guaranteed). The coefficient λ₁ may be set as appropriate. Expression 1 is stored in the memory 13.

### Step S505:

The processing circuitry 15 generates Expression 2 related to generating the (2n+2)th prediction image Pred2 on the basis of the reference data, the (2n+1)th prediction image Pred1, and an n-th CNN. Expression 2 may be expressed as presented below.

x₂ₙ₊₂=CNNₙ(x₂ₙ₊₁, W) Expression 2:

In Expression 2, x₂ₙ₊₁ denotes the (2n+2)th prediction image Pred2. Further, CNNₙ (x₂ₙ₊₁, w) in Expression 2 corresponds to a cGAN capable of receiving inputs of complex numbers and configured to receive the input of the (2n+1)th prediction image Pred1 and to output the (2n+2)th prediction image Pred2, while using the reference data w as a condition. The elements in Expression 2 are expressed by using complex numbers. Expression 2 is stored in the memory 13.

### Step S506:

By employing the reconstructing function 155, the processing circuitry 15 generates a mathematical function f(x) by connecting together solutions of Expression 1 of which the quantity is equal to n and solutions of Expression 2 of which the quantity is equal to n. The mathematical function f(x) is a mathematical function using the prediction image x as an argument and corresponds to the reconstruction image illustrated in FIG. 4. Further, Expression 1 and Expression 2 presented above are merely examples. It is possible to change the expressions to other expressions or the like as appropriate, as long as the technical concepts are similar. The reconstructing function 155 reads a correct answer reconstruction image of the same image type as that of the reconstruction image, from the memory 13. The reconstructing function 155 determines, through a backpropagation method, the plurality of coefficients included in the CNNs of which the quantity is equal to n, so as to minimize an error “Loss” between the read correct answer reconstruction image and the mathematical function f(x). The error “Loss” can be defined as presented below, for example.

Loss=MSE(f(x)−the correct answer reconstruction image)

In the above expression, MSE denotes a mean square error of (f(x)−the correct answer reconstruction image). The definition of the error “Loss” is not limited to the above expression. For example, the error Loss may be defined as presented in the expression below.

Loss=MAE(f(x)−the correct answer reconstruction image)

In the above expression, MAE denotes a mean absolute error of (f(x)−the correct answer reconstruction image). To minimize the Loss, an error backpropagation method may be used, for example. Further, the prescribed coefficient λ₁ corresponds to a hyper parameter, for example. Furthermore, the prescribed coefficient λ₁ may be changed in accordance with the prediction index n.

For example, by employing the reconstructing function 155, the processing circuitry 15 repeatedly performs the training process described above, while all the coefficients in CNNₙ(x₂ₙ₊₁, w) or one or more of the coefficients in CNNₙ(x₂ₙ₊₁, w) trained as the cGAN are fixed. In this situation, during the training process, the cGAN is inference except for the coefficients that are not fixed.

When the additional data k is fingerprinting data, CNNₙ(x₂ₙ₊₁, w) corresponds to the reconstruction DB. In that situation, CNNₙ(x₂ₙ₊₁, w) is dictionary matching, so that the abovementioned training process is repeatedly performed while the coefficients in CNNₙ(x₂ₙ₊₁, w) are fixed. During the training process described above, the dictionary matching is inference. For the dictionary matching, to begin with, all the inputs are a set of representative values. For example, when the value of Δf falls in the range from −100.0 to +100.0, 50 values in the range are arbitrarily selected (at regular intervals, for example). Subsequently, with respect to each of all the values, an observation value is exactly calculated through a physical simulation, so that all the observation values are registered into a dictionary. As above, the training process is completed. When the reconstruction process is performed by using the reconstruction DB, at step S304, the reconstructing function 155 determines the second intermediate reconstruction image Recon2, by conducting a search in the dictionary being the reconstruction DB and, with respect to the first intermediate reconstruction image Recon1 and the reference data w, specifying the closest values thereto or picking out and performing an interpolation with a number of closer values thereto.

### Step S507:

When the consistency between the (2n+1)th prediction image Pred1 and the additional data k has been satisfied approximately (step S507: Yes), the process at step S509 will be performed. For example, when the difference between the intermediate conversion data derived from the (2n+1)th prediction image Pred1 and the additional data k at step S504 is equal to or smaller than a prescribed value, the process at step S509 will be performed. On the contrary, when the consistency between the (2n+1)th prediction image Pred1 and the additional data k has not been satisfied approximately (step S507: No), the process at step S508 will be performed. For example, when the difference between the intermediate conversion data derived from the (2n+1)th prediction image Pred1 and the additional data k at step S504 exceeds the prescribed value, the process at step S508 will be performed. The prescribed value is a value indicating the degree of consistency between the intermediate conversion data derived from the (2n+1)th prediction image Pred1 and the additional data k and, for example, may arbitrarily be set in accordance with the image type of the prediction image. The number of times of repetition at the present step is N.

### Step S508:

The prediction index n is incremented. In other words, the processing circuitry 15 sets n+1 as a new n. Subsequently, the processes at steps S504 through S507 will be performed.

### Step S509:

By employing the reconstructing function 155, the processing circuitry 15 causes the memory 13 to store therein the CNNs of which the quantity is equal to n as a reconstruction model, together with the image type of the reference data w and the image type of the prediction image. After that, by repeatedly performing the reconstruction training process by changing the reference data w and the correct answer reconstruction image while using the same image type, the training of the reconstruction model is completed. Subsequently, the mathematical function f(x) in which the reconstruction model is incorporated is stored into the memory 13 as a trained model. In the reconstruction model, the reconstruction has been designed (trained) by using the complex-valued neural network so that the gain and the phase of the intermediate conversion data are consistent (coherent) with those of the additional data k, while the additional data k is used as a reference. In other words, the reconstruction model has a function of correcting the gain and the phase of the intermediate conversion data so as to be consistent with those of the acquisition data, while the acquisition data is used as the reference. In an example, the generation model may be used while the argument w in the reconstruction model is fixed to 0 (a solid black image).

The data reconstruction device 1 according to the embodiment described above is configured to generate the medical image MI of the image type different from that of the reference data w on the basis of the reference data w, to obtain the acquisition data which is different from the data to be generated related to the generation of the reference data w and was acquired over the imaging period shorter than that of the data to be generated, and to generate the reconstruction image of the image type by correcting the inconsistency of the medical image MI with the acquisition data on the basis of the medical image MI, the acquisition data, and the reference data w. For example, the data reconstruction device 1 according to the embodiment is configured to generate the first intermediate reconstruction image Recon1 by using the medical image so as to reduce the inconsistency with the acquisition data, and to further input the reference data w serving as a condition and the first intermediate reconstruction image Recon1 to the complex-number-based conditional trained model (the reconstruction model) that receives the input of the first intermediate reconstruction image Recon1 and the reference data w and that outputs the second intermediate reconstruction image Recon2, to thereby generate, as the final reconstruction image, the second intermediate reconstruction image Recon2 which is output from the conditional trained model and in which the inconsistency between the first intermediate reconstruction image Recon1 and the acquisition data has been corrected.

With this configuration, because the medical image MI generated on the basis of the reference data w is used as a prediction result, the data reconstruction device 1 according to the embodiment is able to correct the prediction result so as to be consistent with the acquisition data acquired over the imaging period shorter than that of the data to be generated. Consequently, by using the data reconstruction device 1 described herein, it is possible to generate, from the reference data w, a reconstruction image of which the contrast is different from that of the reference data w, e.g., to generate a T2W from a T1W and the acquisition data. Further, as illustrated in FIG. 2, when the reference data w is image data generated from data having a large deviation in the gain and/or the phase such as data derived from a spiral scan, whereas the acquisition data is acquired by performing a scan having a small deviation in the gain and/or the phase such as a Cartesian or radial scan, because the complex neural network is used as the reconstruction model and is trained so as to compensate the deviations in the gain and/or the phase, it is possible to cause the gain and the phase related to the medical image to match those of the acquisition data. In other words, by using the data reconstruction device 1 described herein, even when the manner in which the phase deviates between the acquisition data and the data to be generated changes with respect to each trajectory due to a defect in hardware such as an eddy current in the MRI apparatus, it is possible to generate a reliable reconstruction image by correcting the manner in which the phase deviates so as to match that of the acquisition data.

Further, by using the data reconstruction device 1 described herein, it is possible to generate a reconstruction image desired by the user, for example, by using a past medical image as the reference data w and acquiring the acquisition data with a high under-sampling ratio. It is therefore possible to significantly shorten the acquisition period in medical examinations. Accordingly, it is possible to reduce burdens imposed on the user by the medical examinations and to also improve throughput of the medical examinations.

Consequently, no matter what imaging method is used for acquiring the data to be generated related to the reference data w, it is possible to generate a reconstruction image of the image type different from that of the reference data w, while guaranteeing reliability and image quality of the reconstruction image by ensuring the data consistency with the acquisition data, as well as shortening the acquisition period compared to that of a normal image generating process. For example, it is known that an image obtained by predicting a result of implementing a FLAIR method, which suppresses a water signal, tends to be a different image. However, with the reference data w generated as an image derived from the FLAIR method, by using acquisition data acquired to guarantee data consistency between the prediction result and the acquisition data, it is possible to generate a reconstruction image of an image type different from that of the reference data w, while ensuring reliability. In other words, by using the medical image MI serving as supplemental information based on prior knowledge with respect to the under-sampling acquisition data, the data reconstruction device 1 described herein makes it possible to generate a reconstruction image having high reliability and enhanced image quality by performing the under-sampling reconstruction under the restricted condition while keeping high reliability. For example, even when the reference data w or the medical image is an image generated on the basis of fingerprinting data, it is possible to generate a reconstruction image having high reliability, by correcting the deviations in the data consistency with the acquisition data used additionally.

### Modification Examples

In a modification example, a medical image generated by the generation model is converted into data (hereinafter, “conversion data”) in the same format as that of the acquisition data, so that a difference image of the same image type as that of the medical image is generated on the basis of difference data indicating a difference between the conversion data and the acquisition data, so as to generate a reconstruction image by combining the medical image with the difference image. The present modification example is applied when the generated medical image has high reliability. Technical concepts of the present modification example correspond, for example, to the situation in which the repetition process is omitted from the reconstruction process according to the first embodiment.

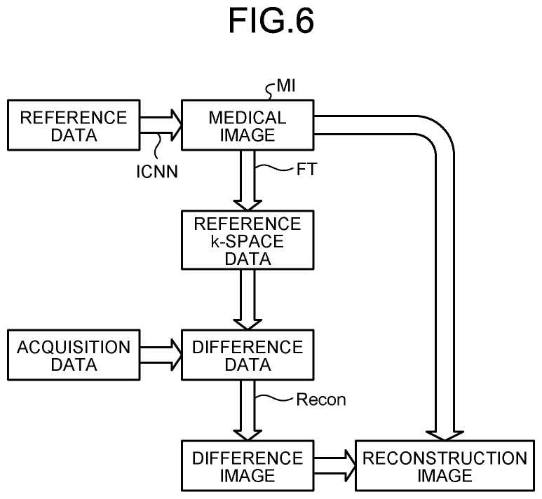

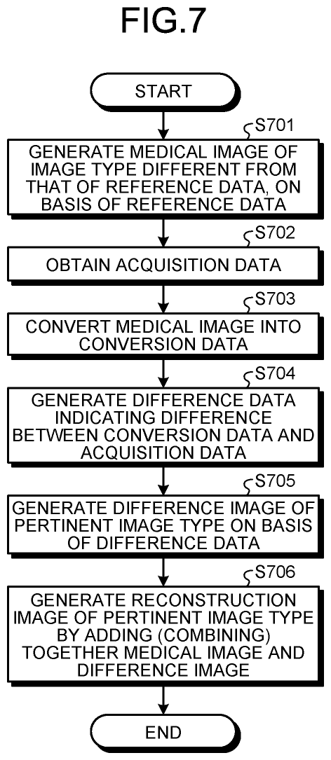

The reconstruction process performed by the data reconstruction device 1 according to the present modification example will be explained, with reference to FIGS. 6 and 7. FIG. 6 is a diagram illustrating an example of an outline of a reconstruction process according to the present modification example. FIG. 7 is a flowchart illustrating an example of a procedure in the reconstruction process according to the present modification example.

The reconstruction process

### Step S701:

By employing the image generating function 153, the processing circuitry 15 generates, with respect to the reference data, the medical image MI of an image type different from that of the reference data. In other words, the image generating function 153 generates the medical image MI by inputting the reference data to a generation model ICNN. Because the process at the present step is the same as the process at step S301, the explanation thereof will be omitted.

### Step S702:

By employing the obtaining function 151, the processing circuitry 15 obtains acquisition data. Because the obtaining of the acquisition data is the same as that at step S301, the explanation thereof will be omitted.

### Step S703:

By employing the reconstructing function 155, the processing circuitry 15 generates the conversion data corresponding to the reference k-space data illustrated in FIG. 6, by converting the medical image into data in the same format as that of the acquisition data. The generation of the conversion data may be realized, for example, by a numerical value calculation using the medical image or by a Fourier transform performed on the medical image. The conversion data corresponds to the intermediate conversion data in the embodiment. Alternatively, when the acquisition data is fingerprinting data, the reconstructing function 155 may generate the conversion data through a matching process with a reverse lookup from a dictionary stored in the memory 13 in advance.

### Step S704:

By employing the reconstructing function 155, the processing circuitry 15 generates difference data indicating the difference between the conversion data and the acquisition data. For example, the reconstructing function 155 generates the difference data by subtracting the acquisition data from the conversion data.

### Step S705:

By employing the reconstructing function 155, the processing circuitry 15 reconstructs a difference image of the same image type as that of the medical image on the basis of the difference data. For example, the processing circuitry 15 generates the difference image by performing an inverse Fourier transform Recon on the difference data. In another example, when the acquisition data is fingerprinting data, the reconstructing function 155 generates a difference image through a matching process with a dictionary (dictionary-based matching).

### Step S706:

By employing the reconstructing function 155, the processing circuitry 15 generates a reconstruction image of the pertinent image type, by adding (combining) together the medical image and the difference image. The reconstruction process according to the modification example has thus ended.

The data reconstruction device 1 according to the modification example of the first embodiment described above is configured to generate the medical image of the image type different from that of the reference data on the basis of the reference data, to generate the conversion data by converting the medical image into the data in the same format as that of the acquisition data, to generate the difference data by calculating the difference between the conversion data and the acquisition data, to generate the difference image of the image type different from that of the reference data on the basis of the difference data, and to generate the reconstruction image by combining the medical image with the difference image. With this configuration, the data reconstruction device 1 according to the present modification example is able to generate the reconstruction image of the image type desired by the user more conveniently and in a shorter time period, without the need to conduct a search using a dictionary (a database) or to use a CNN. Because the other advantageous effects of the present modification example are the same as those of the first embodiment, the explanations thereof will be omitted.

### Second Embodiment

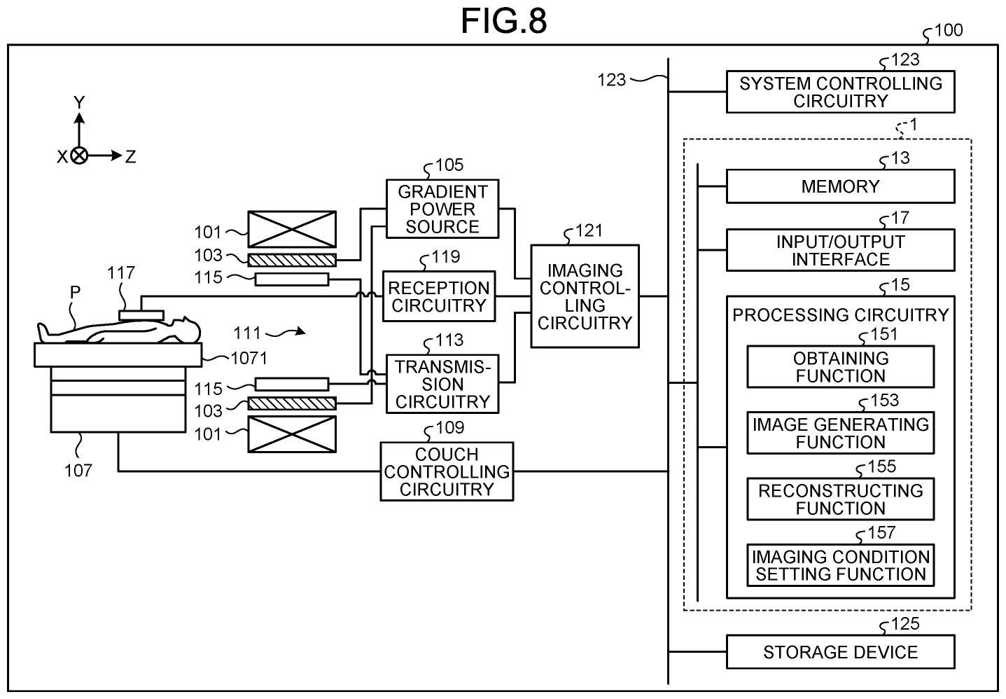

In the present embodiment, an MRI apparatus including the data reconstruction device 1 is configured to determine, on the basis of the reference data, one or both of: a pulse sequence used for acquiring the acquisition data and an imaging parameter related to the pulse sequence. FIG. 8 is a diagram illustrating an example of an MRI apparatus 100 according to the present embodiment. As illustrated in FIG. 8, the processing circuitry 15 included in the MRI apparatus 100 further includes an imaging condition setting function 157. In a modification example of the present embodiment, the imaging condition setting function 157 and an input/output interface 17 may be included in the data reconstruction device 1.

FIG. 8 is a block diagram illustrating an exemplary configuration of the MRI apparatus 100 according to the second embodiment. As illustrated in FIG. 8, the MRI apparatus 100 includes a static magnetic field magnet 101, a gradient coil 103, a gradient power source 105, a couch 107, couch controlling circuitry (a system controlling unit) 109, transmission circuitry 113, a transmission coil 115, a reception coil 117, reception circuitry 119, imaging controlling circuitry (an acquiring unit) 121, system controlling circuitry (a system controlling unit) 123, a storage device 125, and the data reconstruction device 1.

The static magnetic field magnet 101 is a magnet formed to have a hollow and substantially circular cylindrical shape. The static magnetic field magnet 101 is configured to generate a substantially uniform static magnetic field in the space on the inside thereof. For example, a superconductive magnet or the like may be used as the static magnetic field magnet 101.

The gradient coil 103 is a coil formed to have a hollow and substantially circular cylindrical shape and is arranged on the inner surface side of a cooling container having a circular cylindrical shape. By individually receiving a supply of an electric current from the gradient power source 105, the gradient coil 103 is configured to generate gradient magnetic fields of each of which the magnetic intensity changes along X-, Y-, and Z- axes that are orthogonal to one another. For example, the gradient magnetic fields generated by the gradient coil 103 along the X-, Y-, and Z- axes form a slice selecting gradient magnetic field, a phase encoding gradient magnetic field, and a frequency encoding gradient magnetic field (which may be called a readout gradient magnetic field). The slice selecting gradient magnetic field is used for arbitrarily determining an imaged cross-sectional plane. The phase encoding gradient magnetic field is used for changing the phase of a magnetic resonance signal in accordance with a spatial position. The frequency encoding gradient magnetic field is used for changing the frequency of a magnetic resonance signal in accordance with a spatial position.

The gradient power source 105 is a power source device configured to supply the electric currents to the gradient coil 103 under control of the imaging controlling circuitry 121.

The couch 107 is a device including a couchtop 1071 on which a patient P is placed. Under control of the couch controlling circuitry 109, the couch 107 is configured to insert the couchtop 1071 on which the patient P is placed, into a bore 111.

The couch controlling circuitry 109 is circuitry configured to control the couch 107. By driving the couch 107 according to an instruction from an operator received via the input/output interface 17, the couch controlling circuitry 109 moves the couchtop 1071 in longitudinal directions and up-and-down directions, as well as left-and-right directions in some situations.

The transmission circuitry 113 is configured to supply a radio frequency pulse modulated with a Larmor frequency to the transmission coil 115, under control of the imaging controlling circuitry 121. For example, the transmission circuitry 113 includes an oscillating unit, a phase selecting unit, a frequency converting unit, an amplitude modulating unit, a Radio Frequency (RF) amplifier, and the like. The oscillating unit is configured to generate an RF pulse having a resonance frequency unique to a target atomic nucleus positioned in the static magnetic field. The phase selecting unit is configured to select a phase of the RF pulse generated by the oscillating unit. The frequency converting unit is configured to convert the frequency of the RF pulse output from the phase selecting unit. The amplitude modulating unit is configured to modulate the amplitude of the RF pulse output from the frequency converting unit according to a sinc mathematical function, for example. The RF amplifier is configured to amplify the RF pulse output from the amplitude modulating unit and to supply the amplified RF pulse to the transmission coil 115.

The transmission coil 115 is a Radio Frequency (RF) coil arranged on the inside of the gradient coil 103. The transmission coil 115 is configured to generate an RF pulse corresponding to a radio frequency magnetic field, in accordance with the output from the transmission circuitry 113.

The reception coil 117 is an RF coil arranged on the inside of the gradient coil 103. The reception coil 117 is configured to receive a magnetic resonance signal emitted from the patient P due to the radio frequency magnetic field. The reception coil 117 is configured to output the received magnetic resonance signal to the reception circuitry 119. Alternatively, the transmission coil 115 and the reception coil 117 may be implemented while being integrated as a transmission and reception coil.

Under control of the imaging controlling circuitry 121, the reception circuitry 119 is configured to generate a digital Magnetic Resonance (MR) signal (hereinafter, “MR data”) on the basis of the magnetic resonance signal output from the reception coil 117. More specifically, the reception circuitry 119 generates the MR data by performing various types of signal processing processes on the MR signal output from the reception coil 117 and subsequently Performing an Analog to Digital (A/D) conversion on the data resulting from the various types of signal processing processes. The reception circuitry 119 is configured to output the generated MR data to the imaging controlling circuitry 121.

The imaging controlling circuitry 121 is configured to perform an imaging process on the patient P, by controlling the gradient power source 105, the transmission circuitry 113, the reception circuitry 119, and the like, according to an imaging protocol output from the processing circuitry 15. The imaging protocol includes a pulse sequence corresponding to the type of the medical examination. The imaging protocol defines: the magnitude of the electric current to be supplied to the gradient coil 103 by the gradient power source 105; the timing with which the electric current is to be supplied to the gradient coil 103 by the gradient power source 105; the magnitude and the time width of the radio frequency pulse to be supplied to the transmission coil 115 by the transmission circuitry 113; the timing with which the radio frequency pulse is to be supplied to the transmission coil 115 by the transmission circuitry 113; the timing with which the MR signal is to be received by the reception coil 117; and the like. When having received the MR data from the reception circuitry 119 as a result of imaging the patient P by driving the gradient power source 105, the transmission circuitry 113, and the reception circuitry 119, the imaging controlling circuitry 121 transfers the received MR data to the data reconstruction device 1 or the like. For example, by using a pulse sequence to obtain k-space data corresponding to a plurality of mutually-different contrast levels, the imaging controlling circuitry 121 may perform one or both of: imaging related to the data to be generated; and imaging related to the acquiring of the acquisition data. The imaging controlling circuitry 121 is realized by using a processor, for example.

As a hardware resource, the system controlling circuitry 123 includes a processor, memory elements such as a Read-Only Memory (ROM) and/or a RAM, and the like (not illustrated) and is configured to control the MRI apparatus 100 by employing a system controlling function. More specifically, the system controlling circuitry 123 reads a system controlling program stored in the storage device 125, loads the read program into a memory, and controls pieces of circuitry of the MRI apparatus 100 according to the loaded system controlling program. For example, on the basis of an imaging condition input by the operator via the input/output interface 17, the system controlling circuitry 123 reads the imaging protocol from the storage device 125. In an example, the system controlling circuitry 123 may generate the imaging protocol on the basis of the imaging condition. The system controlling circuitry 123 is configured to transmit the imaging protocol to the imaging controlling circuitry 121 so as to control the imaging performed on the patient P. The system controlling circuitry 123 is realized by using a processor, for example. Alternatively, the system controlling circuitry 123 may be incorporated in the processing circuitry 15 included in the data reconstruction device 1. In that situation, the system controlling function is executed by the processing circuitry 15, so that the processing circuitry 15 functions as a substitute for the system controlling circuitry 123.

The storage device 125 is configured to store therein various types of programs executed by the system controlling circuitry 123, various types of imaging protocols, imaging conditions including a plurality of imaging parameters that define the imaging protocols, and the like. For example, the storage device 125 may be a semiconductor memory element such as a RAM or a flash memory, an HDD, an SSD, an optical disk or the like. Alternatively, the storage device 125 may be a CD-ROM drive, a DVD drive, or a drive device configured to read and write various types of information to and from a portable storage medium such as a flash memory. Alternatively, the data stored in the storage device 125 may be stored in the memory 13. In that situation, the memory 13 functions as a substitute for the storage device 125.

The processing circuitry 15 includes the obtaining function 151, the image generating function 153, the reconstructing function 155, and the imaging condition setting function 157. Various types of functions performed by the obtaining function 151, the image generating function 153, the reconstructing function 155, and the imaging condition setting function 157 are stored in the memory 13 in the form of computer-executable programs. The processing circuitry 15 is a processor that realizes the functions corresponding to the programs, by reading the programs corresponding to these various types of functions from the memory 13 and executing the read programs. In other words, the processing circuitry 15 that has read the programs has the plurality of functions illustrated within the processing circuitry 15 in FIG. 8, and the like. Because the obtaining function 151 and the image generating function 153 are the same as those in the first embodiment, the explanations thereof will be omitted. The processing circuitry 15 realizing the imaging condition setting function 157 corresponds to an imaging condition setting unit.

By employing the reconstructing function 155, the processing circuitry 15 is configured to fill the k-space with the magnetic resonance data along the readout direction, according to the intensity of the readout gradient magnetic field. The reconstructing function 155 is configured to generate the MR image by performing an inverse Fourier transform on the magnetic resonance data filling the k-space. The reconstructing function 155 is configured to output the MR image to the memory 13 and/or the input/output interface 17. The reconstructing function 155 is configured to perform the reconstruction processes described in the first embodiment and the modification examples. Because the reconstruction processes are the same as those in the first embodiment and the modification examples, the explanations thereof will be omitted.

By employing the imaging condition setting function 157, the processing circuitry 15 is configured to determine, on the basis of the reference data, one or both of: a pulse sequence (hereinafter, “acquisition sequence”) used for acquiring the acquisition data; and an imaging parameter (hereinafter, “acquisition parameter”) related to the pulse sequence. For example, when the reference data has high image quality, the imaging condition setting function 157 sets, as an acquisition sequence, a pulse sequence in which the number of under-sampling steps (the reduction factor) is increased in the imaging parameter for the acquisition of the data to be generated related to the reference data. In that situation, the increased number of under-sampling steps corresponds to the acquisition parameter. In other words, when the reference data has high image quality, the imaging condition setting function 157 sets the acquisition sequence by increasing the number of under-sampling steps, while making the other imaging parameters the same as those used for acquiring the data to be generated.

In contrast, when the reference data has low image quality, the imaging condition setting function 157 sets, as an acquisition sequence, a pulse sequence in which the number of under-sampling steps (the reduction factor) is decreased in the imaging parameter for the acquisition of the data to be generated related to the reference data. In that situation, the decreased number of under-sampling steps corresponds to the acquisition parameter. In other words, when the reference data has low image quality, the imaging condition setting function 157 sets the acquisition sequence by decreasing the number of under-sampling steps, while making the other imaging parameters the same as those used for acquiring the data to be generated.

In an example, the imaging condition setting function 157 may set the acquisition sequence and the acquisition Parameter by using an under-sampling pattern that is usable with an existing imaging protocol. In this situation, the under-sampling pattern corresponds to a type (a style) of the under-sampling steps in the k-space, for example. As a result, it is possible to cause the manner in which artifacts occur in relation to the acquisition data to be the same as a known pattern. More specifically, it is possible to cause the appearance tendency of artifacts in the reference data to be the same as the appearance tendency of artifacts in the reconstruction image. In yet another example, the imaging condition setting function 157 may set, as the acquisition sequence and the acquisition parameter, an under-sampling pattern of an imaging process that is commonly used in a medical examination in accordance with the type of the medical examination order related to the acquiring of the acquisition data.

Further, the imaging condition setting function 157 is configured to set a gain (hereinafter, “RX gain”) of the RF amplifier included in the transmission circuitry 113 in accordance with the acquisition sequence and the acquisition parameter having been set. The imaging condition setting function 157 is configured to set a gain (hereinafter, “TX gain”) of the MR signal at the reception circuitry 119 in accordance with the acquisition sequence and the acquisition parameter having been set. In other words, the imaging condition setting function 157 is configured to adjust the RX gain and the TX gain in accordance with the reference data. The RX gain and the TX gain are controlled by the imaging controlling circuitry 121 in accordance with the acquisition sequence and the acquisition parameter. In other words, the imaging controlling circuitry 121 is configured to control the RX gain and the TX gain in accordance with the imaging condition of the acquisition data. The imaging controlling circuitry 121 is configured to obtain the acquisition data by imaging the patient P while using the imaging condition, the RX gain, the TX gain, and the like set by the imaging condition setting function 157. The acquisition data will be used in the reconstruction process described above.

The input/output interface 17 includes an input interface and an output interface. The input interface includes, for example, circuitry related to a pointing device such as a mouse or an input device such as a keyboard, and an input terminal from a network, and the like. The circuitry included in the input interface is not limited to circuitry related to physical operation component parts such as the mouse, the keyboard, and/or the like. For example, the input interface may include electrical signal processing circuitry configured to receive an electrical signal corresponding to an input operation from an external input device provided separately from the MRI apparatus 100 and to output the received electrical signal to any of various types of circuitry.

The output interface may be, for example, a display device, an output terminal leading to a network, or the like. Under control of the system controlling circuitry 123, the display device is configured to display various types of MR images reconstructed by the reconstructing function 155, various types of MR images generated by the image generating function 153, various types of information related to imaging and image processing, and the like. For example, the display device is a display apparatus such as a Cathode Ray Tube (CRT) display device, a liquid crystal display device, an organic Electroluminescence (EL) display device, a Light Emitting Diode (LED) display device, a plasma display device, or any other arbitrary display device or monitor known in the relevant technical field.

The data reconstruction device 1 included in the MRI apparatus 100 according to the embodiment described above is configured to determine, on the basis of the reference data, one or both of: the pulse sequence used in the acquiring of the acquisition data; and the imaging parameter related to the pulse sequence. Accordingly, it is possible to determine the pulse sequence and the imaging parameter of the acquisition data in accordance with the image quality, a signal-to-noise (S/N) ratio, and the like of the reference data. By using the MRI apparatus 100 configured in this manner, it is possible to generate a reconstruction image that is better and has higher reliability.

Further, by using the MRI apparatus 100 described herein, it is possible to set the acquisition sequence and the acquisition parameter by using the under-sampling pattern that is usable with an existing imaging protocol. For example, when the MRI apparatus 100 described herein is used, at the time of acquiring the acquisition data, it is possible to use an under-sampling method that is the same as the under-sampling method used in another imaging process. Further, when the MRI apparatus 100 described herein is used, it is possible to determine an under-sampling pattern in accordance with the type of the medical examination related to the acquiring of the acquisition data. As a result, when the MRI apparatus 100 described herein is used, it is possible to cause the manner in which artifacts occur in the reconstruction image generated through the reconstruction process to be the same as a known pattern. Consequently, by using the MRI apparatus 100 described herein, it is possible to improve operability of the user and throughput of medical examinations (efficiency of the medical examinations). Because the other advantageous effects of the present embodiment are the same as those of the first embodiment and the modification examples, the explanations thereof will be omitted.

When technical concepts of the embodiments are realized as a data reconstruction method, the data reconstruction method includes: generating a medical image of an image type different from that of reference data on the basis of the reference data; obtaining acquisition data acquired by using an acquisition method different from that used for data to be generated related to generating the reference data; and generating a reconstruction image of the pertinent image type by correcting inconsistency of the medical image with the acquisition data on the basis of the medical image, the acquisition data, and the reference data. Because the procedure and the advantageous effects of the reconstruction process executed in the data reconstruction method are the same as those in the first embodiment, the explanations thereof will be omitted.

When technical concepts of the embodiments are realized as a non-transitory computer-readable storage medium storing therein a data reconstruction program, the non-transitory computer-readable storage medium storing therein the data reconstruction program causes the computer to realize: generating a medical image of an image type different from that of reference data on the basis of the reference data; obtaining acquisition data acquired by using an acquisition method different from that used for data to be generated related to generating the reference data; and generating a reconstruction image of the pertinent image type by correcting inconsistency of the medical image with the acquisition data on the basis of the medical image, the acquisition data, and the reference data.

For example, it is also possible to realize the reconstruction process by installing the data reconstruction program in a computer included in a modality such as the MRI apparatus 100 or in a PACS server and loading the program into a memory. In that situation, the program capable of causing the computer to implement the method may be distributed as being stored in a storage medium such as a magnetic disk (e.g., a hard disk), an optical disk (e.g., a CD-ROM, a DVD), or a semiconductor memory. Because the processing procedure and the advantageous effects of the data reconstruction program are the same as those in the first embodiment, the explanations thereof will be omitted.

According to at least one aspect of the embodiments and the modification examples described above, it is possible to provide the reconstruction image which has enhanced reliability and of which the acquisition period is shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A data reconstruction device comprising processing circuitry configured:
to generate a medical image of an image type different from that of reference data on a basis of the reference data;
to obtain acquisition data acquired by using an acquisition method different from that used for data to be generated related to generating the reference data; and
to generate a reconstruction image of the image type by correcting inconsistency of the medical image with the acquisition data on a basis of the medical image, the acquisition data, and the reference data.

2. The data reconstruction device according to claim 1, wherein the acquisition data is data acquired through imaging based on a pulse sequence different from that of the data to be generated.

3. The data reconstruction device according to claim 1, wherein the reference data is data obtained by mapping a parameter dependent on an examined subject.

4. The data reconstruction device according to claim 1, wherein
the processing circuitry generates a first intermediate reconstruction image by using the medical image so as to reduce the inconsistency with the acquisition data, and
by inputting the reference data serving as a condition and inputting the first intermediate reconstruction image to a conditional trained model configured to receive the input of the first intermediate reconstruction image and the reference data and to output a second intermediate reconstruction image, the processing circuitry generates, as the reconstruction image, the second intermediate reconstruction image which is output from the conditional trained model and in which inconsistency between the first intermediate reconstruction image and the acquisition data has been corrected.

5. The data reconstruction device according to claim 1, wherein
the processing circuitry generates conversion data by converting the medical image into data in a same format as that of the acquisition data,
the processing circuitry generates difference data by calculating a difference between the conversion data and the acquisition data,
the processing circuitry generates a difference image of the image type on a basis of the difference data, and
the processing circuitry generates the reconstruction image by combining the medical image with the difference image.

6. The data reconstruction device according to claim 1, wherein an image related to the reference data and the reconstruction image have mutually-different contrast levels.

7. The data reconstruction device according to claim 1, wherein, on the basis of the reference data, the processing circuitry determines one or both of: a pulse sequence used for the acquiring of the acquisition data; and an imaging parameter related to the pulse sequence.

8. The data reconstruction device according to claim 7, wherein the processing circuitry sets the pulse sequence and the imaging parameter by using a thinning-out pattern that is usable with an existing imaging protocol.

9. The data reconstruction device according to claim 1, wherein one or both of imaging related to the data to be generated and imaging related to the acquiring of the acquisition data are performed by using a pulse sequence for obtaining k-space data capable of generating a plurality of mutually-different contrast levels.

10. The data reconstruction device according to claim 1, wherein the reference data is data generated from a medical examination performed earlier than a medical examination related to the acquiring of the acquisition data.

11. A data reconstruction method comprising:
generating a medical image of an image type different from that of reference data on a basis of the reference data;
obtaining acquisition data acquired by using an acquisition method different from that used for data to be generated related to generating the reference data; and
generating a reconstruction image of the image type by correcting inconsistency of the medical image with the acquisition data on a basis of the medical image, the acquisition data, and the reference data.

12. A non-transitory computer-readable storage medium storing therein a data reconstruction program that causes a computer to realize:
generating a medical image of an image type different from that of reference data on a basis of the reference data;
obtaining acquisition data acquired by using an acquisition method different from that used for data to be generated related to generating the reference data; and
generating a reconstruction image of the image type by correcting inconsistency of the medical image with the acquisition data on a basis of the medical image, the acquisition data, and the reference data.
